(19) United States
(12) Patent Application Publication
(10) Pub. No.: US 2023/0402436 A1
(43) Pub. Date: Dec. 14, 2023

(54) DISPLAY DEVICE, METHOD OF FABRICATING THE SAME, AND TILED DISPLAY DEVICE

(71) Applicant: Samsung Display Co., LTD., Yongin-si (KR)

(72) Inventors: Jin Ho HYUN, Yongin-si (KR); Oh June KWON, Yongin-si (KR); Woo Yong SUNG, Yongin-si (KR)

(73) Assignee: Samsung Display Co., LTD., Yongin-si (KR)

(21) Appl. No.: 18/328,875

(22) Filed: Jun. 5, 2023

(30) Foreign Application Priority Data
Jun. 8, 2022 (KR) 10-2022-0069767

(51) Int. Cl. H01L 25/075; H01L 33/62; H01L 33/38; H01L 25/16

(52) U.S. Cl. CPC H01L 25/0753; H01L 33/62; H01L 33/382; H01L 25/167

(57) ABSTRACT

A display device may include light emitting elements disposed on a first surface of a substrate, a connection electrode disposed on a second surface of the substrate, and a via layer disposed on the connection electrode, and including at least one depression. The passivation layer may be disposed in the depression of the via layer.

### CROSS-REFERENCE TO RELATED APPLICATION(S)

This application claims priority to and benefits of Korean patent application number 10-2022-0069767 under 35 U.S.C. § 119, filed on Jun. 8, 2022 in the Korean Intellectual Property Office, the entire contents of which are incorporated herein reference.

### BACKGROUND

### 1. Technical Field

Various embodiments of the disclosure relate to a display device, a method of fabricating the display device, and a tiled display device.

### 2. Description of Related Art

Recently, as interest in information display increases, research and development on display devices has been continuously conducted.

### SUMMARY

Various embodiments of the disclosure are directed to a display device capable of preventing a passivation film from being undesirably detached, and a method of fabricating the display device.

Aspects of the disclosure are not limited to the above-stated aspects, and those skilled in the art will clearly understand other not mentioned aspects from the accompanying claims.

An embodiment of the disclosure may provide a display device that may include light emitting elements disposed on a first surface of a substrate, a connection electrode disposed on a second surface of the substrate, a via layer disposed on the connection electrode, and including at least one depression, and a passivation layer disposed in the depression of the via layer.

The depression may include a first depressed pattern. The first depressed pattern may extend in a first direction.

The depression may further include a second depressed pattern. The second depressed pattern may be spaced apart from the first depressed pattern.

The second depressed pattern may extend in the first direction.

The depression may further include a second depressed pattern. The second depressed pattern may extend in a second direction intersecting the first direction.

The depression may further include a third depressed pattern intersecting the first depressed pattern and the second depressed pattern.

The passivation layer may physically contact the via layer.

The depression of the via layer may include a first surface, a second surface facing the first surface, and a third surface disposed between the first surface and the second surface.

The passivation layer may physically contact at least one of the first surface, the second surface, and the third surface of the depression of the via layer.

The display device may further include at least one transistor disposed on the first surface of the substrate.

The display device may further include electrodes that electrically connect the transistor to the light emitting elements.

An embodiment of the disclosure may provide a method of fabricating a display device. The method may include forming a front pattern on a first surface of a substrate, forming a rear pattern on a second surface of the substrate, forming a via layer on the rear pattern, forming at least one depression by etching the via layer, and forming a passivation film on the via layer. The passivation film may be provided in the depression of the via layer.

The method may further include forming a passivation layer on the via layer.

The passivation layer may be provided in the depression of the via layer.

The passivation layer may physically contact the via layer.

The passivation film may physically contact the passivation layer provided in the depression.

Forming of the depression may include forming a first depressed pattern extending in a first direction.

Forming of the depression may further include forming a second depressed pattern intersecting the first depressed pattern.

Forming of the passivation film may include hardening a passivation-film material layer provided in the depression of the via layer.

The passivation-film material layer may be provided by an inkjet printing operation.

An embodiment of the disclosure may provide a tiled display device including display devices adjacent to each other, and a seam connecting the display devices to each other. Each of the display devices may include light emitting elements disposed on a first surface of the substrate, a connection electrode disposed on a second surface of the substrate, and a via layer disposed on the connection electrode, and including at least one depression. A passivation layer may be disposed in the depression of the via layer.

Each of the light emitting elements may include a flip-chip-type micro light emitting diode (LED).

Details of various embodiments are included in the detailed descriptions and drawings.

In accordance with an embodiment, a depression may be formed using a via layer on a rear surface of a substrate to which a passivation film may be attached, so that the passivation film can be prevented from being undesirably detached. Therefore, processability can be enhanced.

The effects of the disclosure are not limited by the foregoing, and other various effects are anticipated herein.

### BRIEF DESCRIPTION OF THE DRAWINGS

FIG. 1 is a schematic plan view illustrating a display device in accordance with an embodiment.

FIGS. 2 and 3 are schematic plan views illustrating a pixel of FIG. 1.

FIG. 4 is a schematic sectional view taken along line A-A′ of FIG. 3.

FIG. 5 is a schematic plan view illustrating a tiled display device including multiple display devices in accordance with an embodiment.

FIG. 6 is an enlarged schematic view of area AA of FIG. 5.

FIG. 7 is a schematic sectional view taken along line B-B′ of FIG. 6.

FIG. 8 is an enlarged schematic view of area BB of FIG. 5.

FIGS. 9 to 12 are schematic sectional views taken along line F-F′ of FIG. 8.

FIGS. 13 to 20 are schematic plan views illustrating a depression in accordance with an embodiment.

FIG. 21 is a schematic block diagram illustrating a tiled display device in accordance with an embodiment.

FIGS. 22 to 31 are schematic sectional views illustrating, by process steps, a method of fabricating the display device in accordance with an embodiment.

### DETAILED DESCRIPTION OF THE EMBODIMENTS

Advantages and features of the disclosure, and methods for achieving the same will be clear with reference to embodiments described herein in detail together with the accompanying drawings. The disclosure is not limited to the following embodiments, and various modifications are possible. These embodiments are provided so that this disclosure will be thorough and complete and will fully convey the concept of the disclosure to those skilled in the art.

The terminology used herein is for the purpose of describing particular embodiments only and is not intended to be limiting of embodiments. In this specification, the terms of a singular form may include plural forms unless specifically mentioned.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean any combination including “A, B, or A and B.”

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Furthermore, the term “coupling” or” connection” may comprehensively refer to physical and/or electrical coupling or connection. The term “coupling” or “connection” may comprehensively refer to direct or indirect coupling or connection and integral or non-integral coupling or connection.

It will be understood that when an element or a layer is referred to as being “on” another element or a layer, it can be directly on, connected to, or coupled to the other element or the layer, or one or more intervening elements or layers may be present. Like reference numerals refer to like elements throughout.

It will be understood that, although the terms “first”, “second”, etc. may be used herein to describe various elements, these elements should not be limited by these terms. These terms are only used to distinguish one element from another element. For instance, a first element discussed below could be termed a second element without departing from the teachings of the disclosure.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

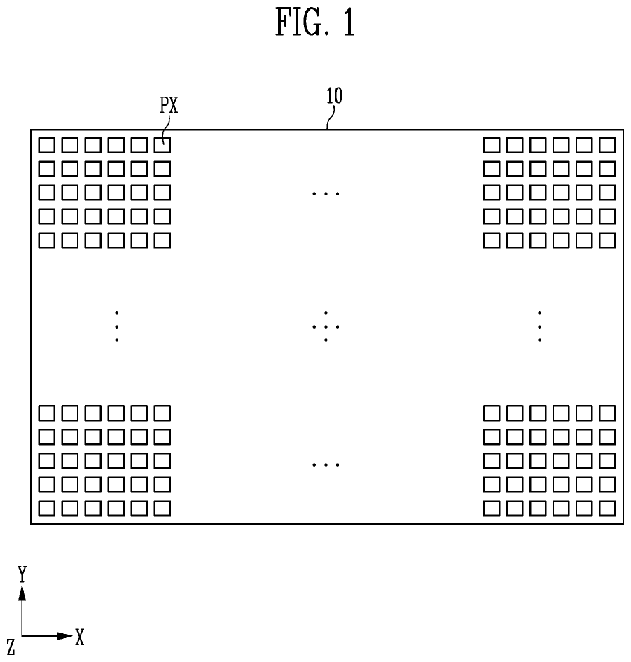

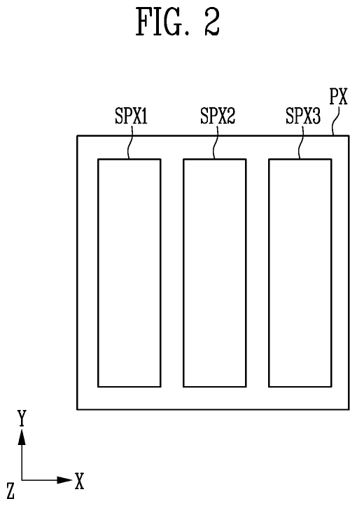

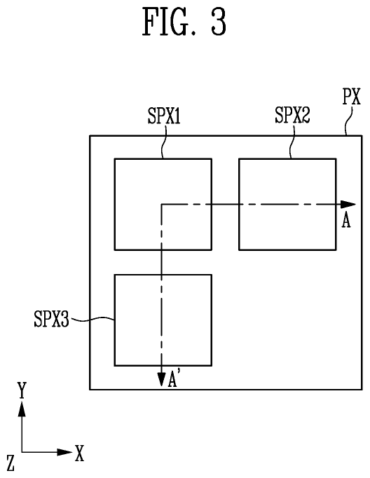

FIG. 1 is a schematic plan view illustrating a display device 10 in accordance with an embodiment. FIGS. 2 and 3 are schematic plan views illustrating a pixel PX of FIG. 1.

Referring to FIG. 1, the display device 10 may be a device configured to display a video or a static image, and may be used not only as portable electronic devices such as a mobile phone, a smart phone, a tablet personal computer (a table PC), a smart watch, a watch phone, a mobile communication terminal, an electronic notebook, an electronic book, a portable multimedia player (PMP), a navigation device, and an ultra mobile PC (UMPC), but also as display screens of various products such as a television, a notebook, a monitor, an advertisement panel, and an internet of things (JOT) device.

The display device 10 may be formed of a rectangular panel having long sides extending in a first direction (an X-axis direction), and short sides extending in a second direction (a Y-axis direction) intersecting the first direction (the X-axis direction). Corners where the long sides extending in the first direction (the X-axis direction) and the short sides extending in the second direction (the Y-axis direction) meet may be rounded with a certain curvature or may be formed at a right angle. The shape of the display device 10 is not limited to a rectangular shape, and may have other polygonal shapes, a circular shape, or an elliptical shape. The display device 10 may be formed to be planar, but it is not limited thereto. For example, the display device 10 may include a curved surface which is formed on each of left and right side edges thereof and has a constant curvature or a varying curvature. The display device 10 may be formed to be flexible so that the display device 10 can be bent, curved, folded, and/or rolled.

The display device 10 may include pixels PX configured to display an image, scan lines extending in the first direction (the X-axis direction), and data lines extending in the second direction (the Y-axis direction). The pixels PX may be arranged in the form of a matrix in the first direction (the X-axis direction) and the second direction (the Y-axis direction).

Each of the pixels PX may include multiple sub-pixels SPX1, SPX2, and SPX3, as illustrated in FIGS. 2 and 3. Although FIGS. 2 and 3 illustrate that each of the pixels PX includes three sub-pixels SPX1, SPX2, and SPX3, i.e., a first sub-pixel SPX1, a second sub-pixel SPX2, and a third sub-pixel SPX3, the disclosure is not limited thereto.

Each of the first sub-pixel SPX1, the second sub-pixel SPX2, and the third sub-pixel SPX3 may be connected to at least one data line among the data lines and at least one scan line among the scan lines.

Each of the first sub-pixel SPX1, the second sub-pixel SPX2, and the third sub-pixel SPX3 may have a rectangular shape, a square shape, or a rhombus shape. For example, each of the first sub-pixel SPX1, the second sub-pixel SPX2, and the third sub-pixel SPX3 may have a rectangular planar shape having short sides extending in the first direction (the X-axis direction) and long sides extending in the second direction (the Y-axis direction), as illustrated in FIG. 2. In other embodiments, each of the first sub-pixel SPX1, the second sub-pixel SPX2, and the third sub-pixel SPX3 may have a square or rhombus planar shape including sides having the same length in the first direction (the X-axis direction) and the second direction (the Y-axis direction), as illustrated in FIG. 3.

As illustrated in FIG. 2, the first sub-pixel SPX1, the second sub-pixel SPX2, and the third sub-pixel SPX3 may be arranged in the first direction (the X-axis direction). In other embodiments, the first sub-pixel SPX1 and any one of the second sub-pixel SPX2 and the third sub-pixel SPX3 may be arranged in the first direction (the X-axis direction), and a remaining one and the first sub-pixel SPX1 may be arranged in the second direction (the Y-axis direction). For example, as illustrated in FIG. 3, the first sub-pixel SPX1 and the second sub-pixel SPX2 may be arranged in the first direction (the X-axis direction), and the first sub-pixel SPX1 and the third sub-pixel SPX3 may be arranged in the second direction (the Y-axis direction).

In other embodiments, the second sub-pixel SPX2 and any one of the first sub-pixel SPX1 and the third sub-pixel SPX3 may be arranged in the first direction (the X-axis direction), and a remaining one and the second sub-pixel SPX2 may be arranged in the second direction (the Y-axis direction). In yet other embodiments, the third sub-pixel SPX3 and any one of the first sub-pixel SPX1 and the second sub-pixel SPX2 may be arranged in the first direction (the X-axis direction), and a remaining one and the third sub-pixel SPX3 may be arranged in the second direction (the Y-axis direction).

The first sub-pixel SPX1 may emit a first color of light. The second sub-pixel SPX2 may emit a second color of light. The third sub-pixel SPX3 may emit a third color of light. Here, the first color may be light in a red wavelength band. The second color may be light in a green wavelength band. The third color may be light in a blue wavelength band. The red wavelength band may be a wavelength band ranging from approximately 600 nm to approximately 750 nm. The green wavelength band may be a wavelength band ranging from approximately 480 nm to approximately 560 nm. The blue wavelength band may be a wavelength band ranging from approximately 370 nm to approximately 460 nm. However, the ranges of the wavelength bands are not limited to the foregoing.

Each of the first sub-pixel SPX1, the second sub-pixel SPX2, and the third sub-pixel SPX3 may include an inorganic light emitting element having an inorganic semiconductor as a light emitting element to emit light. For example, the inorganic light emitting element may be a flip-chip-type micro light emitting diode (LED), but the disclosure is not limited thereto.

As illustrated in FIGS. 2 and 3, the surface area of the first sub-pixel SPX1, the surface area of the second sub-pixel SPX2, and the surface area of the third sub-pixel SPX3 may be substantially the same as each other, but the disclosure is not limited thereto. At least any one of the surface area of the first sub-pixel SPX1, the surface area of the second sub-pixel SPX2, and the surface area of the third sub-pixel SPX3 may be different from another one. In other embodiments, two of the surface area of the first sub-pixel SPX1, the surface area of the second sub-pixel SPX2, and the surface area of the third sub-pixel SPX3 may be substantially the same as each other, and a remaining one may be different from the two. In other embodiments, the surface area of the first sub-pixel SPX1, the surface area of the second sub-pixel SPX2, and the surface area of the third sub-pixel SPX3 may be different from each other.

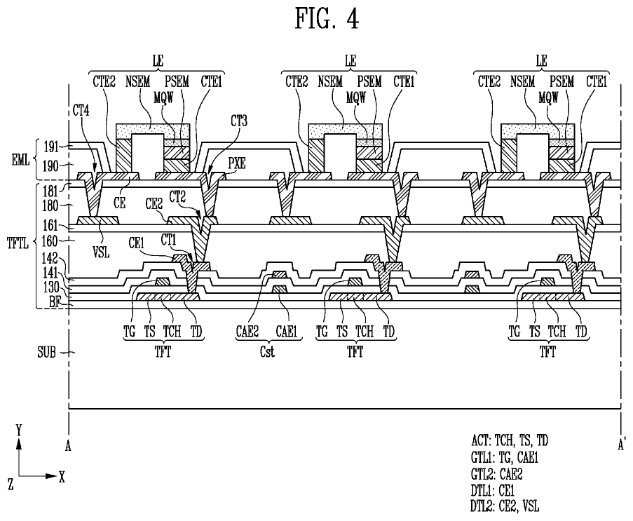

FIG. 4 is a schematic sectional view taken along line A-A′ of FIG. 3.

Referring to FIG. 4, a thin-film transistor layer TFTL may be disposed on the substrate SUB. The thin-film transistor layer TFTL may be a layer in which thin-film transistors TFT are formed.

The thin-film transistor layer TFTL may include an active layer ACT, a first gate layer GTL1, a second gate layer GTL2, a first data metal layer DTL1, and a second data metal layer DTL2.

Furthermore, the thin-film transistor layer TFTL may include a buffer layer BF, a gate insulating layer 130, a first interlayer insulating layer 141, a second interlayer insulating layer 142, a first planarization layer 160, a first insulating layer 161, a second planarization layer 180, and a second insulating layer 181.

The substrate SUB may be a base substrate or a base component for supporting the display device 10. The substrate SUB may be a rigid substrate made of glass. In other embodiments, the substrate SUB may be a flexible substrate which can be bent, folded, and/or rolled. The substrate SUB may include insulating material such as polymer resin, e.g., polyimide (PI).

The buffer layer BFL may be disposed on a surface of the substrate SUB. The buffer layer BF may be a layer for preventing permeation of air or water. The buffer layer BF may be formed of multiple inorganic layers which may be alternately stacked on each other. For example, the buffer layer BFL may have a multilayer structure formed by alternately stacking one or more inorganic layers among a silicon nitride (SiNₓ) layer, a silicon oxynitride (SiOₓN_{y}) layer, a silicon oxide (SiOₓ) layer, a titanium oxide (TiOₓ) layer, and an aluminum oxide (AlOₓ) layer. In an embodiment, the buffer layer BF may be omitted.

The active layer ACT may be disposed on the buffer layer BF. The active layer ACT may include a silicon semiconductor such as a poly-crystal silicon semiconductor, a single-crystal silicon semiconductor, a low temperature poly-crystal silicon semiconductor, and/or an amorphous silicon semiconductor, or may include an oxide semiconductor.

The active layer ACT may include a channel TCH, a first electrode TS, and a second electrode TD of the thin-film transistor TFT. The channel TCH of the thin-film transistor TFT may refer to an area overlapping a gate electrode TG of the thin-film transistor TFT in a third direction (a Z-axis direction) which may be a thickness direction. The first electrode TS of the thin-film transistor TFT may be disposed on a side of the channel TCH, and the second electrode TD thereof may be disposed on another side of the channel TCH. The first electrode TS and the second electrode TD of the thin-film transistor TFT may refer to an area that does not overlap the gate electrode TG in the third direction (the Z-axis direction). The first electrode TS and the second electrode TD of the thin-film transistor TFT may refer to an area which is formed by doping a silicon semiconductor or an oxide semiconductor with ions and thus has conductivity.

The gate insulating layer 130 may be disposed on the active layer ACT. The gate insulating layer 130 may be formed of an inorganic layer made of, for example, silicon nitride (SiNₓ), silicon oxynitride (SiOₓN_{y}), silicon oxide (SiOₓ), titanium oxide (TiOₓ), and/or aluminum oxide (AlOₓ).

The first gate layer GTL1 may be disposed on the gate insulating layer 130. The first gate layer GTL1 may include the gate electrode TG of the thin-film transistor TFT and a first capacitor Cst electrode CAE1. The first gate layer GTL1 may have a single layer or multi-layer structure formed of at least one of molybdenum (Mo), aluminum (Al), chrome (Cr), gold (Au), titanium (Ti), nickel (Ni), neodymium (Nd), and copper (Cu), or an alloy thereof.

The first interlayer insulating layer 141 may be disposed on the first gate layer GTL1. The first interlayer insulating layer 141 may be formed of an inorganic layer made of, for example, silicon nitride (SiNₓ), silicon oxynitride (SiOₓN_{y}), silicon oxide (SiOₓ), titanium oxide (TiOₓ), and/or aluminum oxide (AlOₓ).

The second gate layer GTL2 may be disposed on the first interlayer insulating layer 141. The second gate layer GTL2 may include a second capacitor Cst electrode CAE2. The second gate layer GTL2 may have a single layer or multi-layer structure formed of at least one of molybdenum (Mo), aluminum (Al), chrome (Cr), gold (Au), titanium (Ti), nickel (Ni), neodymium (Nd), and copper (Cu), or an alloy thereof.

The second interlayer insulating layer 142 may be disposed on the second gate layer GTL2. The second interlayer insulating layer 142 may be formed of an inorganic layer made of, for example, silicon nitride (SiNₓ), silicon oxynitride (SiOₓN_{y}), silicon oxide (SiOₓ), titanium oxide (TiOₓ), and/or aluminum oxide (AlOₓ).

The first data metal layer DTL1 including a first connection electrode CE1 may be disposed on the second interlayer insulating layer 142. The first data metal layer DTL1 may have a single layer or multi-layer structure formed of at least one of molybdenum (Mo), aluminum (Al), chrome (Cr), gold (Au), titanium (Ti), nickel (Ni), neodymium (Nd), and copper (Cu), or an alloy thereof.

The first connection electrode CE1 may be connected to the first electrode TS or the second electrode TD of the thin-film transistor TFT through a first contact hole CT1 passing through the gate insulating layer 130, the first interlayer insulating layer 141, and/or the second interlayer insulating layer 142.

The first planarization layer 160 may be formed on the first data metal layer DTL1 so as to remove a step difference formed by the active layer ACT, the first gate layer GTL1, the second gate layer GTL2, and/or the first data metal layer DTL1. The first planarization layer 160 may be formed of an organic layer made of, e.g., acryl resin, epoxy resin, phenolic resin, polyamide resin, polyimide resin, and/or the like.

The first insulating layer 161 may be disposed on the first planarization layer 160. The first insulating layer 161 may be formed of an inorganic layer made of, for example, silicon nitride (SiNₓ), silicon oxynitride (SiOₓN_{y}), silicon oxide (SiOₓ), titanium oxide (TiOₓ), and/or aluminum oxide (AlOₓ).

The second data metal layer DTL2 may be formed on the first insulating layer 161. The second data metal layer DTL2 may include a second connection electrode CE2 and a first power line VSL. The second connection electrode CE2 may be connected to the first connection electrode CE1 through a second contact hole CT2 passing through the first insulating layer 161 and the first planarization layer 160. The second data metal layer DTL2 may have a single layer or multi-layer structure formed of at least one of molybdenum (Mo), aluminum (Al), chrome (Cr), gold (Au), titanium (Ti), nickel (Ni), neodymium (Nd), and copper (Cu), or an alloy thereof.

The second planarization layer 180 may be formed on the second data metal layer DTL2 so as to remove a step difference. The second planarization layer 180 may be formed of an organic layer made of, e.g., acryl resin, epoxy resin, phenolic resin, polyamide resin, polyimide resin, and/or the like.

The second insulating layer 181 may be disposed on the second planarization layer 180. The second insulating layer 181 may be formed of an inorganic layer made of, for example, silicon nitride (SiNₓ), silicon oxynitride (SiOₓN_{y}), silicon oxide (SiOₓ), titanium oxide (TiOₓ), and/or aluminum oxide (AlOₓ).

A light-emitting-element layer EML may be disposed on the second insulating layer 181. The light-emitting-element layer EML may include pixel electrodes PXE, common electrodes CE, and light emitting elements LE. The first sub-pixel SPX1, the second sub-pixel SPX2, and the third sub-pixel SPX3 each may include a light emitting element LE connected to the corresponding pixel electrode PXE and the corresponding common electrode CE. The pixel electrode PXE may be referred to as an anode electrode. The common electrode CE may be referred to as a cathode electrode.

The pixel electrodes PXE and the common electrodes CE may be disposed on the second insulating layer 181. The pixel electrodes PXE each may be connected to the second connection electrode CE2 through a third contact hole CT3 passing through the second insulating layer 181 and the second planarization layer 180. The pixel electrodes PXE each may be connected to the first electrode TS or the second electrode TD of the thin-film transistor TFT through the first connection electrode CE1 and the second connection electrode CE2. Therefore, a pixel voltage or an anode voltage which is controlled by the thin-film transistor TFT may be applied to the pixel electrode PXE.

Each of the common electrodes CE may be connected to the first power line VSL through a fourth contact hole CT4 passing through the second insulating layer 181 and the second planarization layer 180. Hence, a first power voltage of the first power line VSL may be applied to each of the common electrodes CE.

The pixel electrodes PXE and the common electrodes CE may include metal material, such as a stacked structure (Ti/Al/Ti) of aluminum and titanium, a stacked structure (ITO/AI/ITO) of aluminum and ITO, an APC alloy, and a stacked structure (ITO/APC/ITO) of an APC alloy and ITO, having relatively high reflectivity. The APC alloy may be an alloy of silver (Ag), palladium (Pd), and/or copper (Cu).

FIG. 4 illustrates that each of the light emitting elements LE may be a flip-chip-type micro LED in which a first contact electrode CTE1 and a second contact electrode CTE2 are disposed to face the pixel electrode PXE and the common electrode CE. The light emitting element LE may be formed of inorganic material such as GaN. The light emitting element LE may range from several μm to several hundred μm in length in each of the first direction (the X-axis direction), the second direction (the Y-axis direction), and the third direction (the Z-axis direction). For example, the light emitting element LE may be approximately 100 μm or less in length in each of the first direction (the X-axis direction), the second direction (the Y-axis direction), and the third direction (the Z-axis direction).

Each of the light emitting elements LE may be a light emitting structure including an n-type semiconductor NSEM, an active layer MQW, a p-type semiconductor PSEM, a first contact electrode CTE1, and a second contact electrode CTE2.

A portion of the n-type semiconductor NSEM may be disposed on the active layer MQW. A portion of the n-type semiconductor NSEM may be disposed on the second contact electrode CTE2. In an embodiment, a surface of the n-type semiconductor NSEM may face a display surface. The n-type semiconductor NSEM may be formed of GaN doped with an n-type conductive dopant such as Si, Ge, and/or Sn.

The active layer MQW may be disposed on a first portion of a surface of the n-type semiconductor NSEM. The active layer MQW may be interposed between the n-type semiconductor NSEM and the p-type semiconductor PSEM. The active layer MQW may include material having a single or multiple quantum well structure. In the case in which the active layer MQW includes material having a multiple quantum well structure, the active layer MQW may have a structure formed by alternately stacking multiple well layers and multiple barrier layers. Here, although the well layer may be formed of InGaN and the barrier layer may be formed of GaN or AlGaN, the disclosure is not limited thereto. In other embodiments, the active layer MQW may have a structure formed by alternately stacking semiconductor materials having large band gap energy and semiconductor materials having small band gap energy, and may include group-3 to -5 semiconductor materials depending on the wavelength band of light to be emitted.

The p-type semiconductor PSEM may be disposed on a surface of the active layer MQW. The p-type semiconductor PSEM may be formed of GaN doped with a p-type conductive dopant such as Mg, Zn, Ca, Se, and Ba.

The first contact electrode CTE1 may be disposed on the p-type semiconductor PSEM. The second contact electrode CTE2 may be disposed on a second portion of the surface of the n-type semiconductor NSEM. The second portion of the surface of the n-type semiconductor NSEM on which the second contact electrode CTE2 is disposed may be disposed at a position spaced apart from the first portion of the surface of the n-type semiconductor NSEM on which the active layer MQW is disposed.

The first contact electrode CTE1 and the pixel electrode PXE may adhere to each other by an anisotropic conductive film (ACF) or conductive adhesive such as anisotropic conductive paste (ACP). In other embodiments, the first contact electrode CTE1 and the pixel electrode PXE may adhere to each other through a soldering process.

A bank 190 may be disposed on the second insulating layer 181 such that an edge of the pixel electrode PXE and an edge of the common electrode CE are covered with the bank 190. The bank 190 may be formed of an organic layer made of, e.g., acryl resin, epoxy resin, phenolic resin, polyamide resin, polyimide resin, and/or the like.

The bank 190 may be disposed on the third insulating layer 191. The third insulating layer 191 may cover the edge of the pixel electrode PXE and the edge of the common electrode CE. The third insulating layer 191 may be formed of an inorganic layer made of, for example, silicon nitride (SiNₓ), silicon oxynitride (SiOₓN_{y}), silicon oxide (SiOₓ), titanium oxide (TiOₓ), and/or aluminum oxide (AlOₓ).

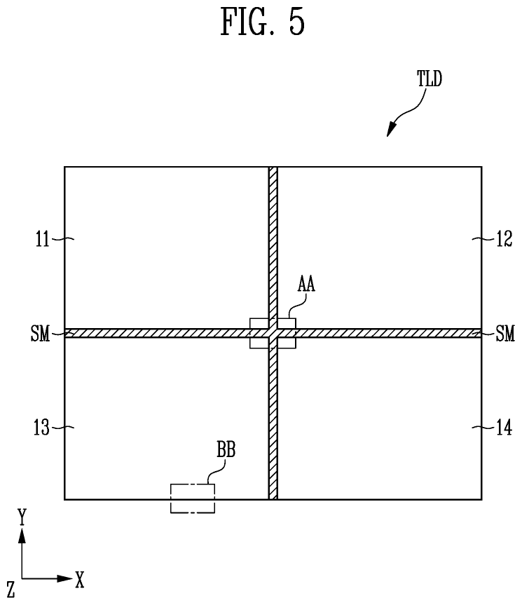

FIG. 5 is a schematic plan view illustrating a tiled display device TLD including multiple display devices in accordance with an embodiment.

Referring to FIG. 5, the tiled display device TLD may include multiple display devices 11, 12, 13, and 14, and a seam SM. For example, the tiled display device TLD may include a first display device 11, a second display device 12, a third display device 13, and a fourth display device 14.

The display devices 11, 12, 13, and 14 may be arranged in a lattice shape. The display devices 11, 12, 13, and 14 may be arranged in the form of a matrix having M rows (M is a positive integer) and N columns (N is a positive integer). For example, the first display device 11 and the second display device 12 may be adjacent to each other in the first direction (the X-axis direction). The first display device 11 and the third display device 13 may be adjacent to each other in the second direction (the Y-axis direction). The third display device 13 and the fourth display device 14 may be adjacent to each other in the first direction (the X-axis direction). The second display device 12 and the fourth display device 14 may be adjacent to each other in the second direction (the Y-axis direction).

The number and arrangement of display devices 11, 12, 13, and 14 in the tiled display device TLD are not limited to those illustrated in FIG. 5. The number and arrangement of display devices 11, 12, 13, and 14 in the tiled display device TLD may be determined depending on the size of each of the display device 10 and the tiled display device TLD and the shape of the tiled display device TLD.

Although the display devices 11, 12, 13, and 14 may have the same size, the disclosure is not limited thereto. For example, in an embodiment, the display devices 11, 12, 13, and 14 may have different sizes.

Each of the display devices 11, 12, 13, and 14 may have a rectangular shape including long sides and short sides. The display devices 11, 12, 13, and 14 may be disposed in such a way that the long sides or the short sides thereof are connected to each other. Some or all of the display devices 11, 12, 13, and 14 may be disposed on an edge of the tiled display device TLD, and may form a side of the tiled display device TLD. At least one display device among the display devices 11, 12, 13, and 14 may be disposed on at least one corner of the tiled display device TLD, and may form two adjacent sides of the tiled display device TLD. At least one display device among the display devices 11, 12, 13, and 14 may be enclosed by the other display devices.

Each of the display devices 11, 12, 13, and 14 may be substantially the same as the display device 10 described with reference to FIGS. 1 to 4. Therefore, description of each of the display devices 11, 12, 13, and 14 will be omitted.

The seam SM may include a coupling component or an adhesive component. The display devices 11, 12, 13, and 14 may be connected to each other by the coupling component or the adhesive component of the seam SM. The seam SM may be disposed between the first display device 11 and the second display device 12, between the first display device 11 and the third display device 13, between the second display device 12 and the fourth display device 14, and between the third display device 13 and the fourth display device 14.

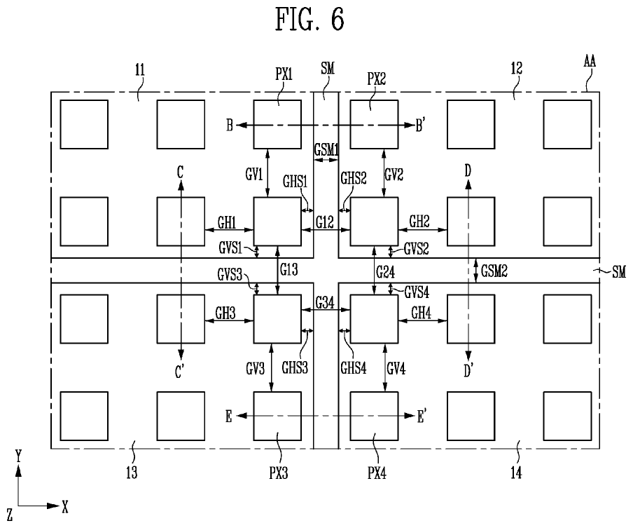

FIG. 6 is an enlarged schematic view of area AA of FIG. 5.

Referring to FIG. 6, the seam SM may have a planar shape of the cross or the plus sign in a central portion of the tiled display device TLD in which the first display device 11, the second display device 12, the third display device 13, and the fourth display device 14 are adjacent to each other. The seam SM may be disposed between the first display device 11 and the second display device 12, between the first display device 11 and the third display device 13, between the second display device 12 and the fourth display device 14, and between the third display device 13 and the fourth display device 14.

The first display device 11 may include first pixels PX1 which are arranged in the form of a matrix in the first direction (the X-axis direction) and the second direction (the Y-axis direction) to display an image. The second display device 12 may include second pixels PX2 which are arranged in the form of a matrix in the first direction (the X-axis direction) and the second direction (the Y-axis direction) to display an image. The third display device 13 may include third pixels PX3 which are arranged in the form of a matrix in the first direction (the X-axis direction) and the second direction (the Y-axis direction) to display an image. The fourth display device 14 may include fourth pixels PX4 which are arranged in the form of a matrix in the first direction (the X-axis direction) and the second direction (the Y-axis direction) to display an image.

A minimum distance between the first pixels PX1 adjacent to each other in the first direction (the X-axis direction) may be defined as a first horizontal spacing distance GH1. A minimum distance between the second pixels PX2 adjacent to each other in the first direction (the X-axis direction) may be defined as a second horizontal spacing distance GH2. The first horizontal spacing distance GH1 and the second horizontal spacing distance GH2 may be substantially the same as each other.

The seam SM may be disposed between the first pixel PX1 and the second pixel PX2 that are adjacent to each other in the first direction (the X-axis direction). A minimum distance G12 between the first pixel PX1 and the second pixel PX2 that are adjacent to each other in the first direction (the X-axis direction) may be the same as the sum of a minimum distance GHS1 between the first pixel PX1 and the seam SM in the first direction (the X-axis direction), a minimum distance GHS2 between the second pixel PX2 and the seam SM in the first direction (the X-axis direction), and a width GSM1 of the seam SM in the first direction (the X-axis direction).

The minimum distance G12 between the first pixel PX1 and the second pixel PX2 that are adjacent to each other in the first direction (the X-axis direction), the first horizontal spacing distance GH1, and the second horizontal spacing distance GH2 may be substantially the same as each other. To this end, the minimum distance GHS1 between the first pixel PX1 and the seam SM in the first direction (the X-axis direction) may be less than the first horizontal spacing distance GH1, and the minimum distance GHS2 between the second pixel PX2 and the seam SM in the first direction (the X-axis direction) may be less than the second horizontal spacing distance GH2. Furthermore, the width GSM1 of the seam SM in the first direction (the X-axis direction) may be less than the first horizontal spacing distance GH1 or the second horizontal spacing distance GH2.

A minimum distance between the third pixels PX3 adjacent to each other in the first direction (the X-axis direction) may be defined as a third horizontal spacing distance GH3. A minimum distance between the fourth pixels PX3 adjacent to each other in the first direction (the X-axis direction) may be defined as a fourth horizontal spacing distance GH4. The third horizontal spacing distance GH3 and the fourth horizontal spacing distance GH4 may be substantially the same as each other.

The seam SM may be disposed between the third pixel PX3 and the fourth pixel PX4 that are adjacent to each other in the first direction (the X-axis direction). A minimum distance G34 between the third pixel PX3 and the fourth pixel PX4 that are adjacent to each other in the first direction (the X-axis direction) may be the same as the sum of a minimum distance GHS3 between the third pixel PX3 and the seam SM in the first direction (the X-axis direction), a minimum distance GHS4 between the fourth pixel PX4 and the seam SM in the first direction (the X-axis direction), and the width GSM1 of the seam SM in the first direction (the X-axis direction).

The minimum distance G34 between the third pixel PX3 and the fourth pixel PX4 that are adjacent to each other in the first direction (the X-axis direction), the third horizontal spacing distance GH3, and the fourth horizontal spacing distance GH4 may be substantially the same as each other. To this end, the minimum distance GHS3 between the third pixel PX3 and the seam SM in the first direction (the X-axis direction) may be less than the third horizontal spacing distance GH3, and the minimum distance GHS4 between the fourth pixel PX4 and the seam SM in the first direction (the X-axis direction) may be less than the fourth horizontal spacing distance GH4. Furthermore, the width GSM1 of the seam SM in the first direction (the X-axis direction) may be less than the third horizontal spacing distance GH3 or the fourth horizontal spacing distance GH4.

A minimum distance between the first pixels PX1 adjacent to each other in the second direction (the Y-axis direction) may be defined as a first vertical spacing distance GV1. A minimum distance between the third pixels PX3 adjacent to each other in the second direction (the Y-axis direction) may be defined as a third vertical spacing distance GV3. The first vertical spacing distance GV1 and the third vertical spacing distance GV3 may be substantially the same as each other.

The seam SM may be disposed between the first pixel PX1 and the third pixel PX3 that are adjacent to each other in the second direction (the Y-axis direction). A minimum distance G13 between the first pixel PX1 and the third pixel PX3 that are adjacent to each other in the second direction (the Y-axis direction) may be the same as the sum of a minimum distance GVS1 between the first pixel PX1 and the seam SM in the second direction (the Y-axis direction), a minimum distance GVS3 between the third pixel PX3 and the seam SM in the second direction (the Y-axis direction), and a width GSM2 of the seam SM in the second direction (the Y-axis direction).

The minimum distance G13 between the first pixel PX1 and the third pixel PX3 that are adjacent to each other in the second direction (the Y-axis direction), the first vertical spacing distance GV1, and the third vertical spacing distance GV3 may be substantially the same as each other. To this end, the minimum distance GVS1 between the first pixel PX1 and the seam SM in the second direction (the Y-axis direction) may be less than the first vertical spacing distance GV1, and the minimum distance GVS3 between the third pixel PX3 and the seam SM in the second direction (the Y-axis direction) may be less than the third vertical spacing distance GV3. Furthermore, the width GSM2 of the seam SM in the second direction (the Y-axis direction) may be less than the first vertical spacing distance GV1 or the third vertical spacing distance GV3.

A minimum distance between the second pixels PX2 adjacent to each other in the second direction (the Y-axis direction) may be defined as a second vertical spacing distance GV2. A minimum distance between the fourth pixels PX4 adjacent to each other in the second direction (the Y-axis direction) may be defined as a fourth vertical spacing distance GV4. The second vertical spacing distance GV2 and the fourth vertical spacing distance GV4 may be substantially the same as each other.

The seam SM may be disposed between the second pixel PX2 and the fourth pixel PX4 that are adjacent to each other in the second direction (the Y-axis direction). A minimum distance G24 between the second pixel PX2 and the fourth pixel PX4 that are adjacent to each other in the second direction (the Y-axis direction) may be the same as the sum of a minimum distance GVS2 between the second pixel PX2 and the seam SM in the second direction (the Y-axis direction), a minimum distance GVS4 between the fourth pixel PX4 and the seam SM in the second direction (the Y-axis direction), and the width GSM2 of the seam SM in the second direction (the Y-axis direction).

The minimum distance G24 between the second pixel PX2 and the fourth pixel PX4 that are adjacent to each other in the second direction (the Y-axis direction), the second vertical spacing distance GV2, and the fourth vertical spacing distance GV4 may be substantially the same as each other. To this end, the minimum distance GVS2 between the second pixel PX2 and the seam SM in the second direction (the Y-axis direction) may be less than the second vertical spacing distance GV2, and the minimum distance GVS4 between the fourth pixel PX4 and the seam SM in the second direction (the Y-axis direction) may be less than the fourth vertical spacing distance GV4. Furthermore, the width GSM2 of the seam SM in the second direction (the Y-axis direction) may be less than the second vertical spacing distance GV2 or the fourth vertical spacing distance GV4.

As illustrated in FIG. 6, so as to prevent the seam SM between images displayed on the display devices 11, 12, 13, and 14 from being visible, the minimum distance between the pixels of the adjacent display devices may be substantially the same as the minimum distance between the pixels in each of the display devices.

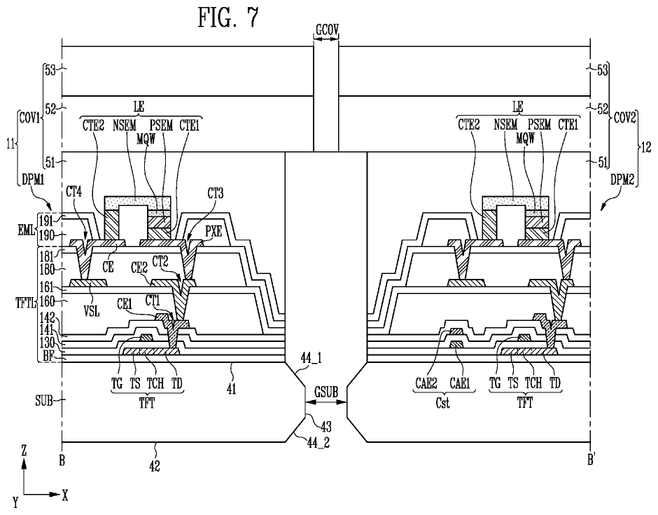

FIG. 7 is a schematic sectional view taken along line B-B′ of FIG. 6.

Referring to FIG. 7, the first display device 11 may include a first display module DPM1 and a first front cover COV1. The second display device 12 may include a second display module DPM2 and a second front cover COV2.

Each of the first display module DPM1 and the second display module DPM2 may include a substrate SUB, a thin-film transistor layer TFTL, and a light-emitting-element layer EML. Because the thin-film transistor layer TFTL and the light-emitting-element layer EML have been described in detail with reference to FIG. 4, redundant description thereof will be omitted.

The substrate SUB may include a first surface 41 on which the thin-film transistor layer TFTL is disposed, a second surface 42 which faces the first surface 41, and a first side surface 43 disposed between the first surface 41 and the second surface 42. The first surface 41 may be a front surface or an upper surface of the substrate SUB. The second surface 42 may be a rear surface or a lower surface of the substrate SUB.

The substrate SUB may further include chamfers 44_1 and 44_2 disposed between the first surface 41 and the first side surface 43 and between the second surface 42 and the first side surface 43. The thin-film transistor layer TFTL and the light emitting element layer EML may not be disposed on the chamfers 44_1 and 44_2. Thanks to the chamfers 44_1 and 44_2, the substrate SUB of the first display device 11 and the substrate of the second display device 12 can be prevented from being damaged by collision therebetween.

The chamfers 44_1 and 44_2 may also be disposed between the first surface 41 and each of the other side surfaces except the first side surface 43 and between the second surface 42 and each of the other side surfaces except the first side surface 43. For example, in the case in which the first display device 11 and the second display device 12 each have a rectangular planar shape, as illustrated in FIG. 5, the chamfers 44_1 and 44_2 of the substrate SUB may be disposed between the first surface 41 and each of a second side surface, a third side surface, and a fourth side surface, and between the second surface 42 and each of the second side surface, the third side surface, and the fourth side surface.

The first front cover COV1 may be disposed on the chamfers 44_1 and 44_2 of the substrate SUB. In other words, the first front cover COV1 may protrude farther than the substrate SUB in the first direction (the X-axis direction) and the second direction (the Y-axis direction). Therefore, a distance GSUB between the substrate SUB of the first display device 11 and the substrate SUB of the second display device 12 may be greater than a distance GCOV between the first front cover COV1 and the second front cover COV2.

Each of the first front cover COV1 and the second front cover COV2 may include an adhesive component 51, a light transmittance control layer 52 disposed on the adhesive component 51, and an anti-glare layer 53 disposed on the light transmittance control layer 52.

The adhesive component 51 of the first front cover COV1 may function to attach the first front cover COV1 to the light-emitting-element layer EML of the first display module DPM1. The adhesive component 51 of the second front cover COV2 may function to attach the second front cover COV2 to the light-emitting-element layer EML of the second display module DPM2. The adhesive component 51 may be a transparent adhesive component which allows light to pass therethrough. For example, the adhesive component 51 may be formed of an optically clear adhesive film or optically clear adhesive resin.

The anti-glare layer 53 may be designed to irregularly reflect external light so that the visibility of an image can be prevented from deteriorating due to direct reflection of the external light. Therefore, a contrast ratio of images displayed on the first display device 11 and the second display device 12 may be increased.

The light transmittance control layer 52 may be designed to reduce the transmittance of external light or light reflected by the first display module DPM1 and the second display module DPM2. Hence, a gap formed by the distance GSUB between the substrate SUB of the first display module DPM1 and the substrate SUB of the second display module DPM2 can be prevented from being visible from the outside.

The anti-glare layer 53 may be implemented as a polarizing plate, and the light transmittance control layer 52 may be implemented as a phase delay layer, but the disclosure is not limited thereto.

The cross-sectional structures of the tiled display device taken along line C-C′, D-D′, and E-E′ of FIG. 6 may be substantially the same as the cross-sectional structure of the tiled display device taken along line B-B′ and illustrated in FIG. 7; therefore, detailed description thereof will be omitted.

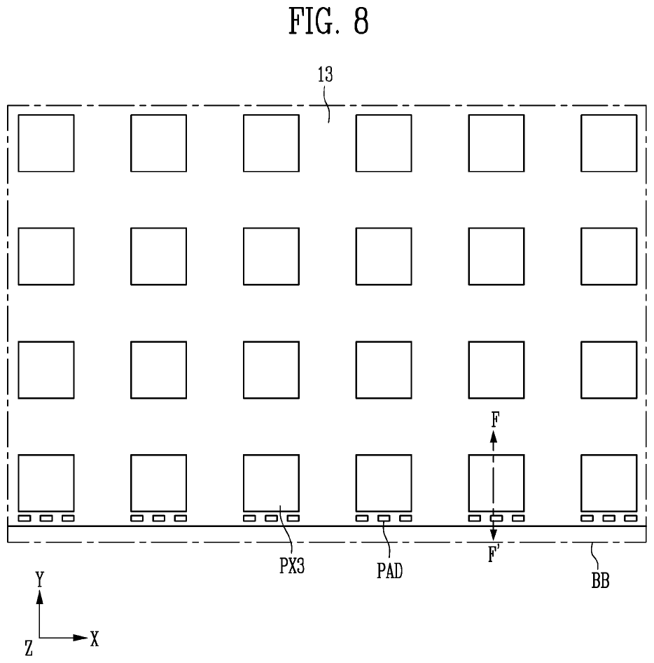

FIG. 8 is an enlarged schematic view of area BB of FIG. 5.

For the convenience of description, FIG. 8 illustrates the third pixels PX3 and pads PAD disposed in a lower portion of the third display device 13. The first display device 11, the second display device 12, and the fourth display device 14 may have substantially the same configuration as that of the third display device 13; therefore, redundant explanation thereof will be omitted.

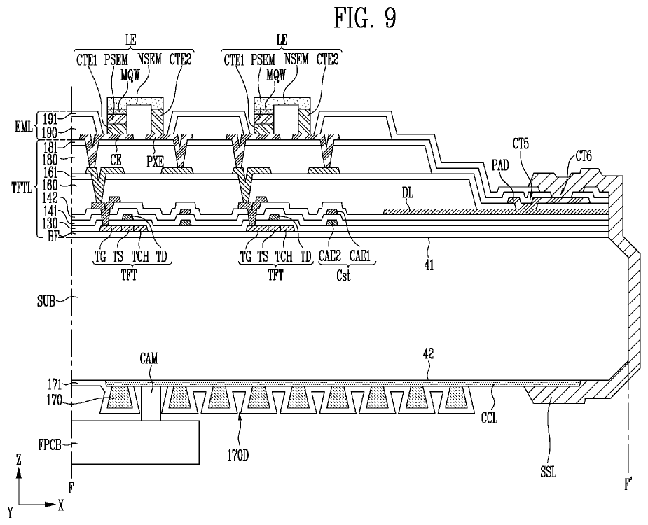

Referring to FIG. 8, the pads PAD may be disposed on a lower peripheral portion of the third display device 13. In the case where data lines (DL of FIG. 9) of the third display device 13 extend in the second direction (the Y-axis direction), the pads PAD may be disposed on an upper peripheral portion and the lower peripheral portion of the third display device 13. In the case where the data lines (DL of FIG. 9) of the third display device 13 extend in the first direction (the X-axis direction), the pads PAD may be disposed on a left peripheral portion and a right peripheral portion of the third display device 13.

Each of the pads PAD may be connected to the corresponding data line DL on the first surface 41 of the substrate SUB. Furthermore, each of the pads PAD may be connected to a corresponding side line SSL. The side line SSL may extend from the first surface 41 of the substrate SUB to the second surface 42. The side line SSL may be connected to a connection electrode (CCL of FIG. 9) on the second surface 42 of the substrate SUB.

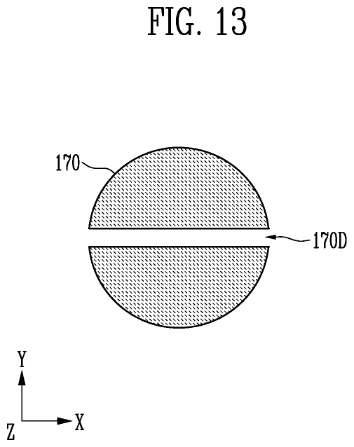

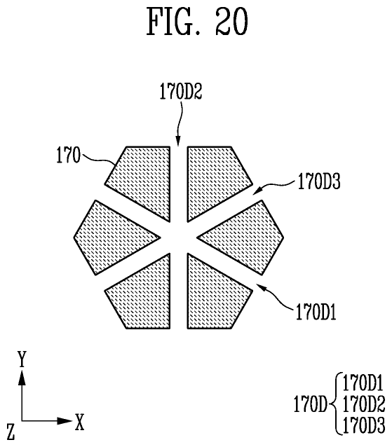

FIGS. 9 to 12 are schematic sectional views taken along line F-F′ of FIG. 8. FIGS. 13 and 20 are schematic plan views illustrating a depression in accordance with an embodiment.

In FIGS. 9 to 12, like reference numerals are used to designate the same components as those of the sectional view of FIG. 4, and redundant description overlapping the description of FIG. 4 will be omitted.

Referring to FIGS. 9 to 12, the pad PAD may be disposed on the first insulating layer 161. A portion of the pad PAD may be exposed rather than being covered with the second insulating layer 181 or the third insulating layer 191. The pad PAD may include the same material as that of the pixel electrodes PXE and the common electrodes CE. For example, the pad PAD may include metal material, such as a stacked structure (Ti/Al/Ti) of aluminum and titanium, a stacked structure (ITO/AI/ITO) of aluminum and ITO, an APC alloy, and a stacked structure (ITO/APC/ITO) of an APC alloy and ITO, having relatively high reflectivity.

The first data metal layer (DTL1 of FIG. 4) may include the data line DL. The data line DL may be disposed on the second interlayer insulating layer 142. In other words, the data line DL may be disposed on the same layer as the first connection electrode CE1, and may include the same material as the first connection electrode CE1.

The pad PAD may be connected to the data line DL through a fifth contact hole CT5 pass through the first planarization layer 160, the first insulating layer 161, the second planarization layer 180, and/or the second insulating layer 181.

The connection electrode CCL may be disposed on the second surface 42 of the substrate SUB. The connection electrode CCL may have a single layer or multi-layer structure formed of at least one of molybdenum (Mo), aluminum (Al), chrome (Cr), gold (Au), titanium (Ti), nickel (Ni), neodymium (Nd), and copper (Cu), or an alloy thereof.

A via layer 170 may be disposed on the connection electrode CCL. The via layer 170 may partially expose the connection electrode CCL. The via layer 170 may be formed of an organic layer made of, e.g., acryl resin, epoxy resin, phenolic resin, polyamide resin, polyimide resin, or the like.

The via layer 170 may include at least one depression 170D. The depression 170D of the via layer 170 may be space in which a passivation film (PF of FIG. 29) to be described below is provided or attached, and may function to prevent the passivation film PF from being undesirably detached from the substrate SUB.

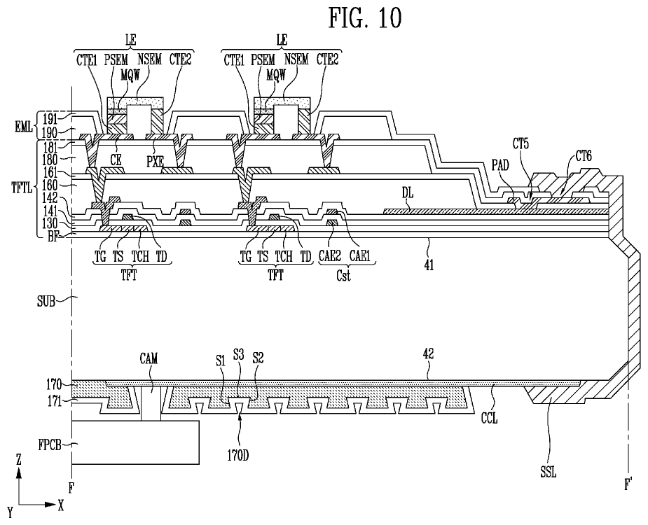

As illustrated in FIGS. 9 and 10, the depression 170D of the via layer 170 may have an inverted tapered shape, in a sectional view. In other words, a side surface of the depression 170D of the via layer 170 may have an inverted tapered shape. The side surface of the depression 170D of the via layer 170 may form an obtuse angle with the second surface 42 of the substrate SUB. Furthermore, as illustrated in FIG. 9, the depression 170D of the via layer 170 may pass through the via layer 170 and expose the connection electrode CCL. However, the disclosure is not limited thereto. As illustrated in FIG. 10, the depression 170D of the via layer 170 may include a first surface S1, a second surface S2 facing the first surface S1, and a third surface S3 disposed between the first surface S1 and the second surface S2. The first surface S1 and the second surface S2 each may form a side surface of the depression 170D of the via layer 170, and the third surface S3 may form a bottom of the depression 170D of the via layer 170.

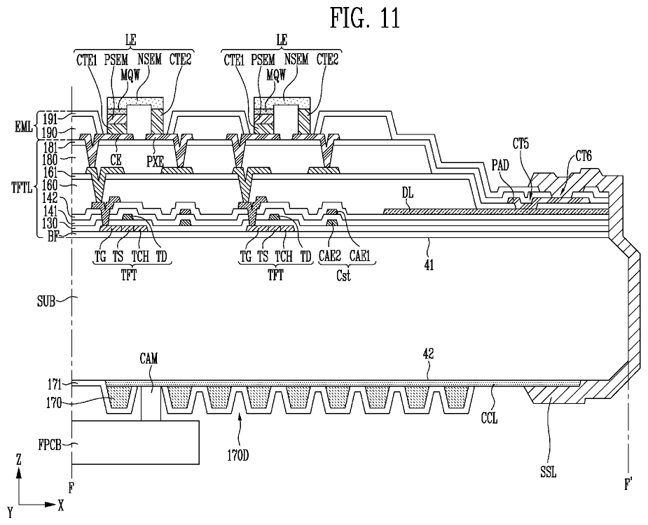

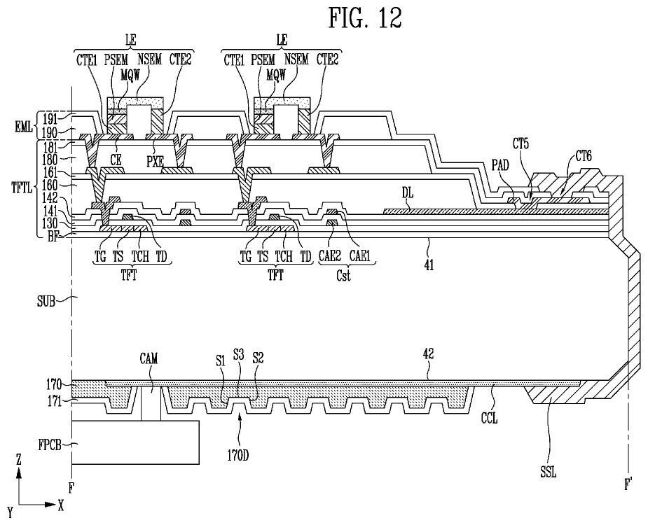

As illustrated in FIGS. 11 and 12, the depression 170D of the via layer 170 may have a tapered shape, in a sectional view. In other words, a side surface of the depression 170D of the via layer 170 may have a tapered shape. The side surface of the depression 170D of the via layer 170 may form an acute angle with the second surface 42 of the substrate SUB. Furthermore, as illustrated in FIG. 11, the depression 170D of the via layer 170 may pass through the via layer 170 and expose the connection electrode CCL. However, the disclosure is not limited thereto. As illustrated in FIG. 12, the depression 170D of the via layer 170 may include a first surface S1, a second surface S2 facing the first surface S1, and a third surface S3 disposed between the first surface S1 and the second surface S2. The first surface S1 and the second surface S2 each may form a side surface of the depression 170D of the via layer 170, and the third surface S3 may form a bottom of the depression 170D of the via layer 170.

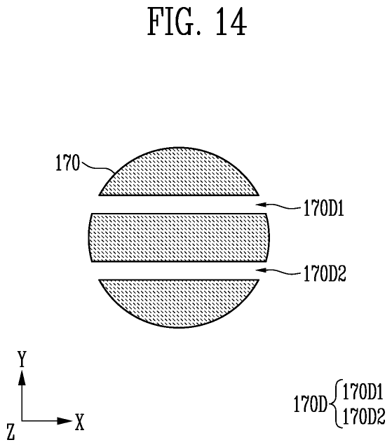

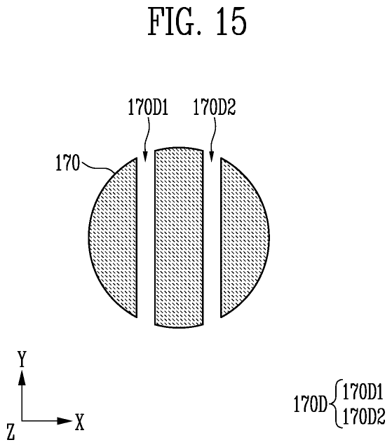

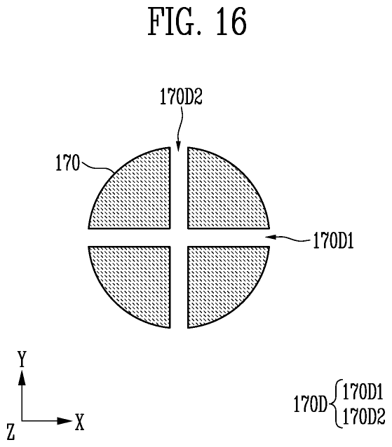

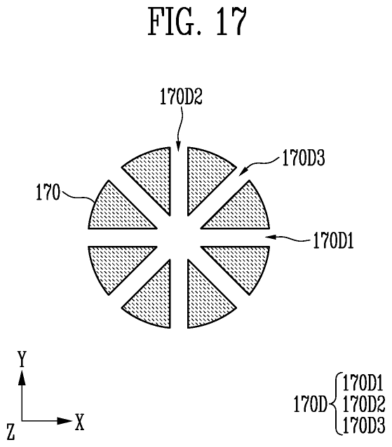

As illustrated in FIG. 13, the depression 170D of the via layer 170 may extend in the first direction (the X-axis direction), in a plan view. As illustrated in FIG. 14, the depression 170D of the via layer 170 may include a first depressed pattern 170D1 and a second depressed pattern 170D2 which are spaced apart from each other in a plan view. For example, the depression 170D of the via layer 170 may include a first depressed pattern 170D1 and a second depressed pattern 170D2 which extend in the first direction (the X-axis direction). In other embodiments, as illustrated in FIG. 15, the depression 170D of the via layer 170 may include a first depressed pattern 170D1 and a second depressed pattern 170D2 which extend in the second direction (the Y-axis direction). In yet other embodiments, as illustrated in FIG. 16, the depression 170D of the via layer 170 may include a first depressed pattern 170D1 and a second depressed pattern 170D2 which intersect each other in a plan view. For example, the depression 170D of the via layer 170 may include a first depressed pattern 170D1 extending in the first direction (the X-axis direction), and a second depressed pattern 170D2 extending in the second direction (the Y-axis direction). In yet other embodiments, as illustrated in FIG. 17, the depression 170D of the via layer 170 may include a first depressed pattern 170D1, a second depressed pattern 170D2, and/or a third depressed pattern 170D3 which intersect each other in a plan view. For example, the depression 170D of the via layer 170 may include a first depressed pattern 170D1 extending in the first direction (the X-axis direction), a second depressed pattern 170D2 extending in the second direction (the Y-axis direction), and a third depressed pattern 170D3 intersecting the first depressed pattern 170D1 and the second depressed pattern 170D2.

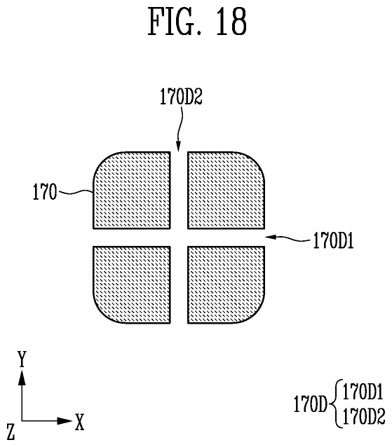

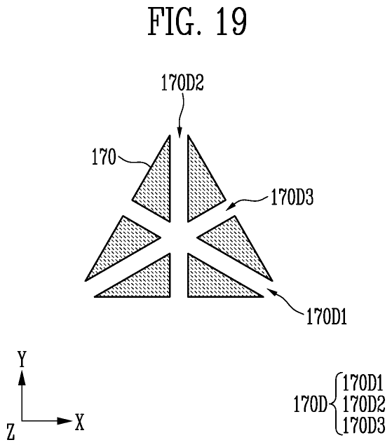

Although FIGS. 13 to 17 illustrate the case where a planar shape or pattern of the via layer 170 is circular, the present disclosure is not limited thereto. For example, as illustrated in FIG. 18, the via layer 170 may have a rounded-corner square including a first depressed pattern 170D1 and a second depressed pattern 170D2. In other embodiments, as illustrated in FIG. 19, the via layer 170 may have a triangular shape including first to third depressed patterns 170D1, 170D2, and 170D3 which intersect each other. In yet other embodiments, as illustrated in FIG. 20, the via layer 170 may have a hexagonal shape including first to third depressed patterns 170D1, 170D2, and 170D3 which intersect each other. In other words, the via layer 170 and the depression 170D may be changed in shape and number.

Referring again to FIGS. 9 to 12, a passivation layer 171 may be disposed on the via layer 170. Although the passivation layer 171 may include one or more of silicon nitride (SiNₓ), silicon oxynitride (SiOₓN_{y}), silicon oxide (SiOₓ), titanium oxide (TiOₓ), and aluminum oxide (AlOₓ), the disclosure is not limited thereto.

The passivation layer 171 may be disposed in the depression 170D of the via layer 170. The passivation layer 171 may contact the via layer 170. In other words, the passivation layer 171 may contact a side surface of the depression 170D of the via layer 170. For example, the passivation layer 171 may contact the first surface 51, the second surface S2, and/or the third surface S3 of the depression 170D of the via layer 170.

A first end of the side line SSL may be connected to the pad PAD. The first end of the side line SSL may be connected to the pad PAD through a sixth contact hole CT6 passing through the third insulating layer 191 and/or the second insulating layer 181. A second end of the side line SSL may be connected to the connection electrode CCL that is exposed from the via layer 170. Hence, the side line SSL may connect the pad PAD formed on the first surface 41 of the substrate SUB with the connection electrode CCL on the second surface 42 of the substrate SUB.

A flexible film FPCB may be disposed on the second surface 42 of the substrate SUB. The flexible film FPCB may be connected, by a conductive adhesive component CAM, to the connection electrode CCL that is exposed from the via layer 170 and/or the passivation layer 171.

A source driving circuit for supplying data voltages to the data lines DL may be disposed on a lower surface of the flexible film FPCB. The conductive adhesive component CAM may be an anisotropic conductive film or anisotropic conductive paste.

As illustrated in FIGS. 8 and 9, in the third display device 13, the source driving circuit of the flexible film FPCB disposed under the substrate SUB may be connected to the data line DL through the connection electrode CCL, the side line SSL, and the pad PAD. In other words, because the source driving circuit is disposed on the substrate SUB, a non-display area (NDA) can be removed, so that the pixels PX may be formed on even the perimeter of the substrate SUB.

In accordance with an embodiment, because the depression 170D is formed using the via layer 170 on the rear surface of the substrate SUB to which the passivation film is to be attached, the passivation film can be prevented from being detached.

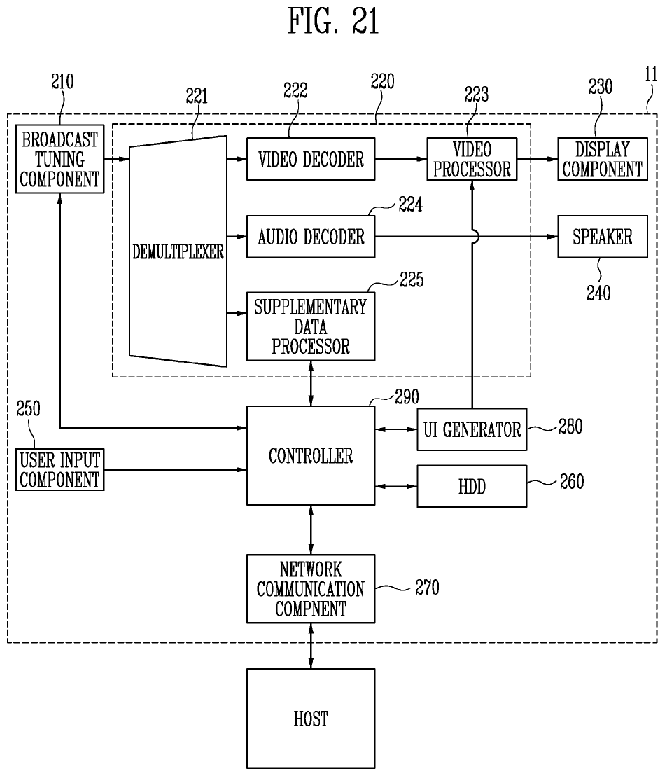

FIG. 21 is a schematic block diagram illustrating the tiled display device TLD in accordance with an embodiment.

For the convenience of description, FIG. 21 illustrates the first display device 11 and a host system HOST.

Referring to FIG. 21, the tiled display device TLD in accordance with an embodiment may include the host system HOST, a broadcast tuning component 210, a signal processor 220, a display component 230, a speaker 240, a user input component 250, an HDD 260, a network communication component 270, an UI generator 280, and/or a controller 290.

The host system HOST may be implemented as a television system, a home theater system, a set-top box, a navigation system, a DVD player, a Blu-ray player, a personal computer (PC), a mobile phone system, and a tablet PC.

Commands from the user may be inputted to the host system HOST in various ways. For example, the host system HOST may receive a command by a touch input from the user. In other embodiments, a command from the user may be inputted to the host system HOST by an input from a keyboard or a button input from a remote controller.

The host system HOST may receive original video data corresponding to original images from an external device. The host system HOST may divide the original video data by the number of display devices. For example, in response to the first display device 11, the second display device 12, the third display device 13, and the fourth display device 14, the host system HOST may divide the original video data into first video data corresponding to a first image, second video data corresponding to a second image, third video data corresponding to a third image, and fourth video data corresponding to a fourth image. The host system HOST may transmit the first video data to the first display device 11, transmit the second video data to the second display device 12, transmit the third video data to the third display device 13, and transmit the fourth video data to the fourth display device 14

The first display device 11 may display the first image in response to the first video data. The second display device 12 may display the second image in response to the second video data. The third display device 13 may display the third image in response to the third video data. The fourth display device 14 may display the fourth image in response to the fourth video data. Hence, the user may watch the original image formed by a combination of the first to fourth images displayed on the first to fourth display devices 11, 12, 13, and 14.

The first display device 11 may include the broadcast tuning component 210, the signal processor 220, the display component 230, the speaker 240, the user input component 250, the HDD 260, the network communication component 270, the UI generator 280, and the controller 290.

The broadcast tuning component 210 may tune a certain channel frequency under the control of the controller 290 and receive a broadcast signal of a corresponding channel through an antenna. The broadcast tuning component 210 may include a channel detection module and an RF demodulation module.

The broadcast signal demodulated by the broadcast tuning component 210 may be processed by the signal processor 220 and outputted to the display component 230 and the speaker 240. Here, the signal processor 220 may include a demultiplexer 221, a video decoder 222, a video processor 223, an audio decoder 224, and a supplementary data processor 225.

The demultiplexer 221 may divide the demodulated broadcast signal into a video signal, an audio signal, and supplementary data. The video signal, the audio signal, and the supplementary data that are divided from each other may be respectively restored by the video decoder 222, the audio decoder 224, and the supplementary data processor 225. Here, the video decoder 222, the audio decoder 224, and the supplementary data processor 225 may restore the video signal, the audio signal, and the supplementary data in decoding formats in response to encoding formats provided in case that the broadcast signal is transmitted.

The decoded video signal may be converted by the video processor 223 to a signal corresponding to a vertical frequency, a resolution, an aspect ratio, and the like that correspond to output specifications of the display component 230. The decoded audio signal may be outputted to the speaker 240.

The display component 230 may include a display panel on which an image displayed, and a panel driver configured to control the operation of the display panel.

The user input component 250 may receive a signal transmitted from the host system HOST. The user input component 250 makes it possible to input not only data about selection of a channel transmitted from the host system HOST, and selection and manipulation of a user interface (UI) menu, but also data about selection and input of a command from the user for communication with other display devices.

The HDD 260 may be provided to store various software programs including an OS program, a recorded broadcast program, a video, a picture, other data, and may be formed of a storage medium such as a hard disk or a non-volatile memory.

The network communication component 270 may be provided for local area communication with the host system HOST and other display devices, and may be implemented as a communication module including an antenna pattern which can embody mobile communication, data communication, Bluetooth, RF, Ethernet, and the like.

The network communication component 270 may transceive radio signals with at least one of a base station, an external terminal, and a server through the antenna pattern to be described below, on a mobile communication network constructed according to technology standards or communication schemes for mobile communication {e.g., a global system for mobile communication (GSM), code division multi access (CDMA), code division multi access 2000 (CDMA2000), enhanced voice-data optimized or enhanced voice-data only (EV-DO), wideband CDMA (WCDMA), high speed downlink packet access (HSDPA), high speed uplink packet access (HSUPA), long term evolution (LTE), long term evolution-advanced (LTE-A), and 5G}.

The network communication component 270 may transceive radio signals through the antenna pattern to be described below, on a communication network according to wireless internet technologies. The wireless internet technologies may include, for example, wireless LAN (WLAN), wireless-fidelity (Wi-Fi), Wi-Fi direct, digital living network alliance (DLNA), wireless broadband (WiBro), world interoperability for microwave access (WiMAX), high speed downlink packet access (HSDPA), high speed uplink packet access (HSUPA), long term evolution (LTE), long term evolution-advanced (LTE-A), and the like. The antenna pattern may transceive data according to at least one wireless internet technology within a range including not only the above-mentioned technologies but also other internet technologies.

The UI generator 280 may generate a UI menu for communication with the host system HOST and other display devices, and may be implemented by an algorithm code and OSD IC. The UI menu for communication with the host system HOST and other display devices 12, 13, 14 may be a menu for designating a target digital TV desired to communicate therewith and selecting a desired function.

The controller 290 may take charge of the overall control of the first display device 11, and may take charge of the control of communication with the host system HOST and the second to fourth display devices 12, 13, and 14. The controller 290 may be implemented as a micro controller unit (MCU) in which a corresponding algorithm code for the control is stored, and which conducts the stored algorithm code.

The controller 290 may control the first display device 11 to transmit, in response to an input from and selection of the user input component 250, a corresponding control command and data to the host system HOST and the second to fourth display device 12, 13, and 14 through the network communication component 270. Of course, in the case where a certain control command and data are inputted from the host system HOST and the second to fourth display devices 12, 13, and 14, an operation may be performed under a corresponding control command.

A block diagram of the second display device 12, a block diagram of the third display device 13, and a block diagram of the fourth display device 14 each may be substantially the same as the block diagram of the first display device 11; therefore, detailed description thereof will be omitted.

Hereinafter, a method of fabricating the display device in accordance with an embodiment will be described.

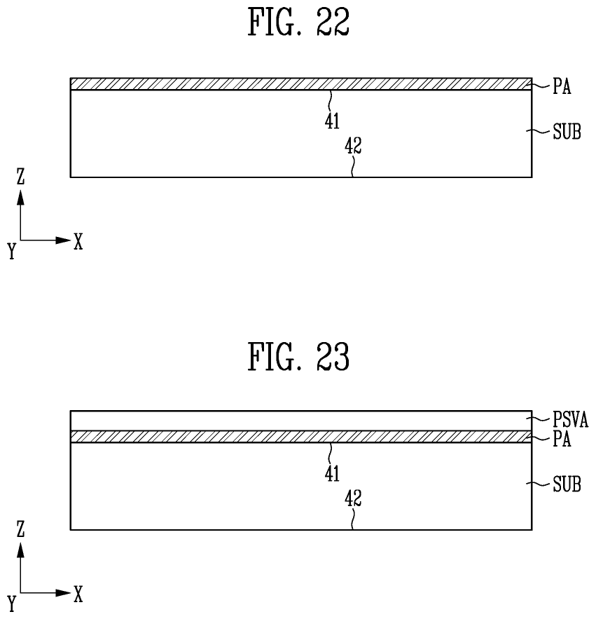

FIGS. 22 to 31 are schematic sectional views illustrating, by process steps, the method of fabricating the display device in accordance with an embodiment. FIGS. 22 to 31 are sectional views for describing the method of fabricating the display device of FIGS. 1 to 21, and for the convenience of description, the illustration is simplified, and detailed reference numerals will be omitted.

Referring to FIG. 22, a front pattern PA may be formed on the first surface 41 of the substrate SUB. The front pattern PA may include the thin-film transistor layer TFTL and/or the light-emitting-element layer EML that is described above.

Thereafter, referring to FIG. 23, a front passivation layer PSVA may be formed on the front pattern PA. Although the front passivation layer PSVA may include one or more of silicon nitride (SiNₓ), silicon oxynitride (SiOₓN_{y}), silicon oxide (SiOₓ), titanium oxide (TiOₓ), and aluminum oxide (AlOₓ), the disclosure is not limited thereto.

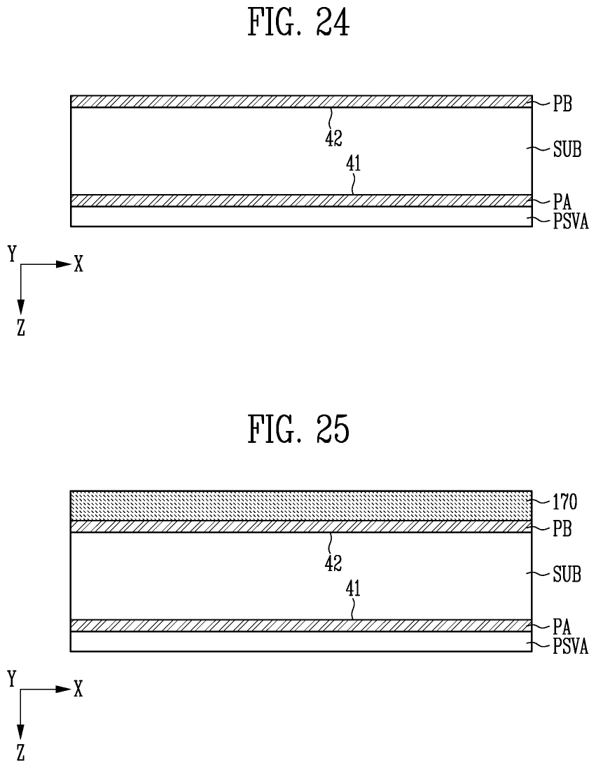

Subsequently, referring to FIG. 24, the substrate SUB may be turned upside down, and a rear pattern PB may be formed on the second surface 42 of the substrate SUB. The rear pattern PB may include the above-stated connection electrode CCL, or the like.

Subsequently, referring to FIG. 25, the via layer 170 may be formed on the rear pattern PB. The via layer 170 may be formed of an organic layer made of, e.g., acryl resin, epoxy resin, phenolic resin, polyamide resin, polyimide resin, and/or the like.

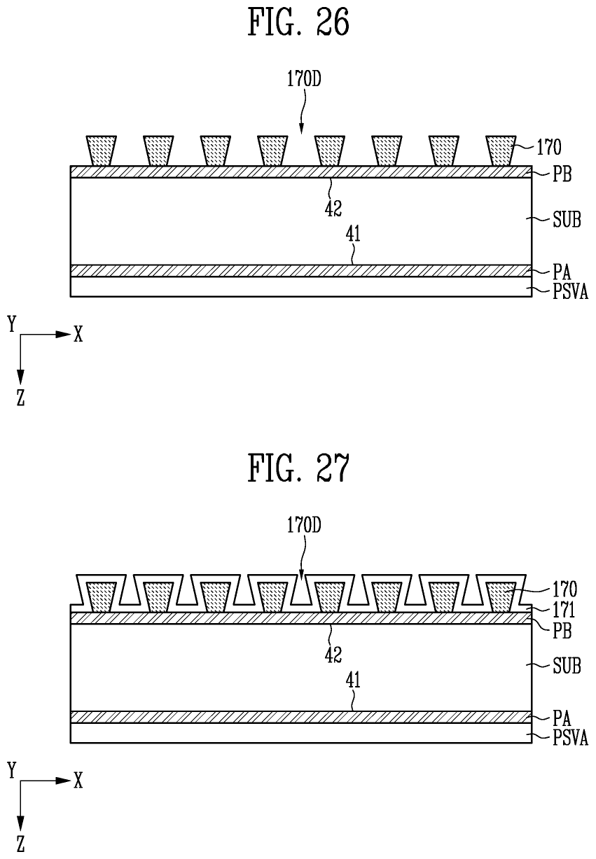

Thereafter, referring to FIG. 26, at least one depression 170D may be formed by etching the via layer 170. The depression 170D may allow the rear pattern PB disposed under the via layer 170 to be exposed. In other embodiments, as described with reference to FIG. 10, the depression 170D may include the first surface (51 of FIG. 10), the second surface (S2 of FIG. 10), and/or the third surface (S3 of FIG. 10). Furthermore, a side surface of the depression 170D may have an inverted tapered shape. In other embodiments, as described with reference to FIGS. 11 and 12, the side surface of the depression 170D may have a tapered shape. In yet other embodiments, as illustrated in FIGS. 13 to 20, the depression 170D may include the first depressed pattern 170D1, the second depressed pattern 170D2, and/or the third depressed pattern 170D3. The first depressed pattern 170D1, the second depressed pattern 170D2, and/or the third depressed pattern 170D3 each may extend in the first direction (the X-axis direction) and/or the second direction (the Y-axis direction). For example, the first depressed pattern 170D1, the second depressed pattern 170D2, and/or the third depressed pattern 170D3 may be spaced apart from each other, and may extend in the same direction, or extend in different directions and intersect each other.

Thereafter, referring to FIG. 27, the passivation layer 171 may be formed on the via layer 170. The passivation layer 171 may be provided in the depression 170D of the via layer 170. The passivation layer 171 may contact the via layer 170. In other words, the passivation layer 171 may contact a side surface of the depression 170D of the via layer 170.

Although the passivation layer 171 may include one or more of silicon nitride (SiNₓ), silicon oxynitride (SiOₓN_{y}), silicon oxide (SiOₓ), titanium oxide (TiOₓ), and aluminum oxide (AlOₓ), the disclosure is not limited thereto.

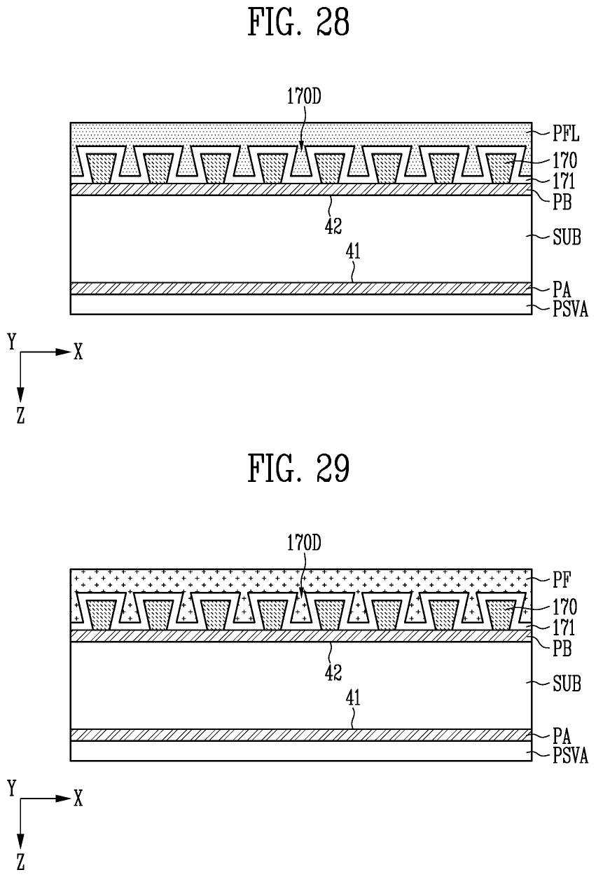

Subsequently, referring to FIGS. 28 and 29, a passivation-film material layer PFL may be provided on the via layer 170 and the passivation layer 171, and the passivation film PF may be formed by hardening the passivation-film material layer PFL.

The passivation-film material layer PFL may be provided on the passivation layer 171 in the depression 170D of the via layer 170. The passivation-film material layer PFL may contact the passivation layer 171 provided in the depression 170D of the via layer 170.

As the passivation-film material layer PFL provided in the depression 170D of the via layer 170 is hardened, the passivation film PF may be formed or coupled in the depression 170D of the via layer 170, so that the passivation film PF can be prevented from being undesirably detached from the substrate SUB. Therefore, a subsequent process may be reliably performed, so that the processability can be enhanced. Although the passivation-film material layer PFL may be provided in the form of ink and formed by an inkjet printing scheme, the disclosure is not limited thereto.

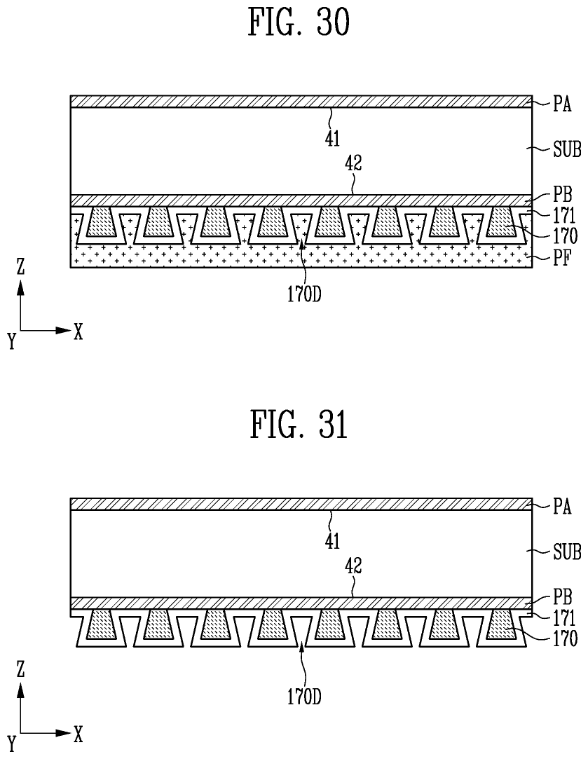

Subsequently, referring to FIGS. 30 and 31, the substrate SUB may be turned upside down, and the front passivation layer PSVA may be removed by etching, and the passivation film PF may be removed, thus completing the display device of FIGS. 1 to 21.

In accordance with an embodiment, because the depression 170D is formed using the via layer 170 on the rear surface of the substrate SUB to which the passivation film PF is to be attached, the passivation film PF can be prevented from being undesirably detached, whereby the processability can be enhanced.

It will be understood by those skilled in the art that various changes in form and details may be made therein without departing from the spirit and scope of the disclosure. Therefore, the foregoing embodiments should be considered in a descriptive sense only and not for purposes of limitation.

What is claimed is:

1. A display device comprising:
light emitting elements disposed on a first surface of a substrate;
a connection electrode disposed on a second surface of the substrate,
a via layer disposed on the connection electrode, and including at least one depression; and
a passivation layer disposed in the depression of the via layer.

2. The display device according to claim 1, wherein
the depression includes a first depressed pattern, and
the first depressed pattern extends in a first direction.

3. The display device according to claim 2, wherein
the depression further includes a second depressed pattern, and
the second depressed pattern is spaced apart from the first depressed pattern.

4. The display device according to claim 3, wherein
the second depressed pattern extends in the first direction.

5. The display device according to claim 2, wherein
the depression further includes a second depressed pattern, and
the second depressed pattern extends in a second direction intersecting the first direction.

6. The display device according to claim 5, wherein
the depression further includes a third depressed pattern, and
the third depressed pattern intersects the first depressed pattern and the second depressed pattern.

7. The display device according to claim 1, wherein
the passivation layer physically contacts the via layer.

8. The display device according to claim 1, wherein
the depression of the via layer includes a first surface, a second surface facing the first surface, and a third surface disposed between the first surface and the second surface.

9. The display device according to claim 8, wherein
the passivation layer physically contacts at least one of the first surface, the second surface, and the third surface of the depression of the via layer.

10. The display device according to claim 1, further comprising:
at least one transistor disposed on the first surface of the substrate.

11. The display device according to claim 10, further comprising:
electrodes that electrically connect the transistor to the light emitting elements.

12. A method of fabricating a display device, comprising:
forming a front pattern on a first surface of a substrate;
forming a rear pattern on a second surface of the substrate;
forming a via layer on the rear pattern;
forming at least one depression by etching the via layer; and
forming a passivation film on the via layer,
wherein the passivation film is provided in the depression of the via layer.

13. The method according to claim 12, further comprising:
forming a passivation layer on the via layer.

14. The method according to claim 13, wherein
the passivation layer is provided in the depression of the via layer.

15. The method according to claim 14, wherein
the passivation layer physically contacts the via layer.

16. The method according to claim 15, wherein
the passivation film physically contacts the passivation layer provided in the depression.

17. The method according to claim 12, wherein the forming of the depression comprises forming a first depressed pattern extending in a first direction.

18. The method according to claim 17, wherein the forming of the depression further comprises forming a second depressed pattern intersecting the first depressed pattern.

19. The method according to claim 12, wherein the forming of the passivation film comprises hardening a passivation-film material layer provided in the depression of the via layer.

20. The method according to claim 19, wherein the passivation-film material layer is provided by an inkjet printing operation.

21. A tiled display device comprising:
display devices adjacent to each other; and
a seam connecting the display devices to each other,
wherein each of the display devices comprises:
light emitting elements disposed on a first surface of a substrate;
a connection electrode disposed on a second surface of the substrate;
a via layer disposed on the connection electrode, and including at least one depression; and
a passivation layer disposed in the depression of the via layer.

22. The tiled display device according to claim 21, wherein each of the light emitting elements comprises a flip-chip-type micro light emitting diode (LED).
